(19) United States
(12) Patent Application Publication
(10) Pub. No.: US 2024/0258393 A1
(43) Pub. Date: Aug. 1, 2024

(54) GATE STRUCTURES AND SEMICONDUCTOR DEVICES INCLUDING THE SAME

(71) Applicant: SAMSUNG ELECTRONICS CO., LTD., Suwon-si (KR)

(72) Inventors: Hyojung NOH, Suwon-si (KR); Sungnam LYU, Suwon-si (KR); Byounghoon LEE, Suwon-si (KR); Jangeun LEE, Suwon-si (KR); Eulji JEONG, Suwon-si (KR)

(21) Appl. No.: 18/544,767

(22) Filed: Dec. 19, 2023

(30) Foreign Application Priority Data
Jan. 26, 2023 (KR) 10-2023-0009861

(51) Int. Cl. H01L 29/423; H10B 12/00

(52) U.S. Cl. CPC H01L 29/42372; H01L 29/42364; H10B 12/315; H01L 29/4236

(57) ABSTRACT

A gate structure includes a first conductive pattern including a first metal or a first metal compound and being doped with a second metal or silicon; a second conductive pattern on the first conductive pattern, the second conductive pattern including a third metal; and a gate insulation pattern covering a lower surface and a sidewall of the first conductive pattern and a sidewall of the second conductive pattern; wherein a work function of the second metal is smaller than a work function of the first metal and is smaller than a work function of the first metal compound.

### CROSS-REFERENCE TO RELATED APPLICATION

This application claims priority under 35 U.S.C. § 119 to Korean Patent Application No. 10-2023-0009861 filed on Jan. 26, 2023, in the Korean Intellectual Property Office, the disclosure of which is hereby incorporated by reference in its entirety.

### BACKGROUND

### 1. Field

Embodiments relate to a gate structure and a semiconductor device including the same.

### 2. Description of the Related Art

A DRAM device may include a gate structure.

### SUMMARY

The embodiments may be realized by providing a gate structure including a first conductive pattern including a first metal or a first metal compound and being doped with a second metal or silicon; a second conductive pattern on the first conductive pattern, the second conductive pattern including a third metal; and a gate insulation pattern covering a lower surface and a sidewall of the first conductive pattern and a sidewall of the second conductive pattern; wherein a work function of the second metal is smaller than a work function of the first metal and is smaller than a work function of the first metal compound.

The embodiments may be realized by providing a gate structure including a first conductive pattern including a first metal compound and being doped with a first metal or silicon; a second conductive pattern on the first conductive pattern, the second conductive pattern including a second metal; and a third conductive pattern on the second conductive pattern, the third conductive pattern being doped with a fourth metal and including a third metal or a second metal compound, wherein a work function of the first metal is smaller than a work function of the first metal compound.

The embodiments may be realized by providing a semiconductor device including a substrate; an active pattern on the substrate; an isolation pattern covering a sidewall of the active pattern; a gate structure extending through upper portions of the active pattern and the isolation pattern in a first direction substantially parallel to an upper surface of the substrate; a bit line structure on a central portion of the active pattern, the bit line structure extending in a second direction substantially parallel to the upper surface of the substrate; a contact plug structure contacting each opposite end portions of the active pattern; and a capacitor structure on the contact plug structure; wherein the gate structure includes a first conductive pattern including a first metal compound, the first conductive pattern being doped with a first metal or silicon, a second conductive pattern on the first conductive pattern, the second conductive pattern including a second metal, a third conductive pattern on the second conductive pattern, a gate mask on the third conductive pattern, and a gate insulation pattern covering a lower surface and a sidewall of the first conductive pattern, a sidewall of the second conductive pattern, and a sidewall of the third conductive pattern, and a work function of the first metal is smaller than a work function of the first metal compound.

### BRIEF DESCRIPTION OF THE DRAWINGS

Features will be apparent to those of skill in the art by describing in detail exemplary embodiments with reference to the attached drawings in which:

FIG. 1 is a cross-sectional view illustrating a first gate structure according to example embodiments.

FIGS. 2 to 4 are cross-sectional views of stages in a method of forming a first gate structure in accordance with example embodiments.

FIG. 5 is a cross-sectional view illustrating a second gate structure in accordance with example embodiments.

FIG. 6 is a cross-sectional view illustrating a third gate structure in accordance with example embodiments.

FIG. 7 is a cross-sectional view illustrating a fourth gate structure in accordance with example embodiments.

FIG. 8 is a plan view illustrating a semiconductor device in accordance with example embodiments, and FIG. 9 is a cross-sectional view taken along line A-A′ of FIG. 8.

FIGS. 10 to 25 are plan views and cross-sectional views of stages in a method of manufacturing a semiconductor device according to example embodiments.

### DETAILED DESCRIPTION

The above and other aspects and features of the gate structures and the methods of manufacturing the same, the semiconductor devices including the gate structures and the methods of manufacturing the same in accordance with example embodiments will become readily understood from detail descriptions that follow, with reference to the accompanying drawings. It will be understood that, although the terms “first,” “second,” and/or “third” may be used herein to describe various materials, layers, regions, pads, electrodes, patterns, structure and/or processes, these various materials, layers, regions, pads, electrodes, patterns, structure and/or processes should not be limited by these terms. These terms are only used to distinguish one material, layer, region, pad, electrode, pattern, structure or process from another material, layer, region, pad, electrode, pattern, structure or process, and are not intended to imply or require sequential inclusion. Thus, “first”, “second” and/or “third” may be used selectively or interchangeably for each material, layer, region, electrode, pad, pattern, structure or process respectively.

Hereinafter, two directions among horizontal directions that are substantially parallel to an upper surface of a substrate 10 or a substrate 100, which may be substantially orthogonal to each other, may be referred as first and second directions D1 and D2, respectively, and a direction among the horizontal directions, which may have an acute angle with respect to each of the first and second directions D1 and D2, may be referred to as a third direction D3. Additionally, a direction substantially perpendicular to the upper surface of the substrate 10 or the substrate 100 may be referred to as a vertical direction.

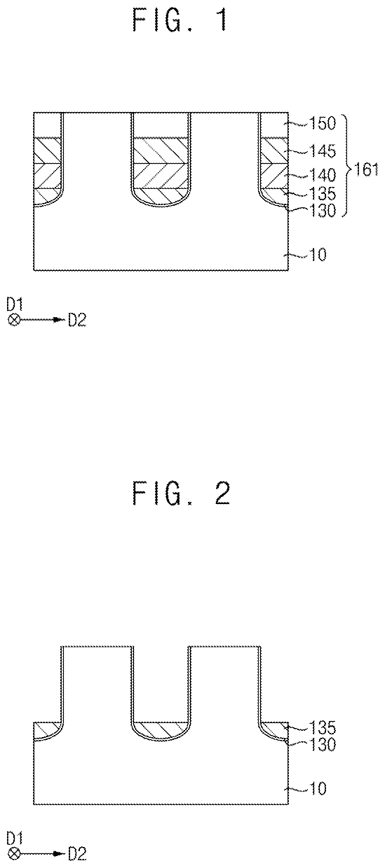

FIG. 1 is a cross-sectional view illustrating a first gate structure according to example embodiments.

The substrate 10 may include silicon, germanium, silicon-germanium, or a III-V group compound semiconductor, e.g., GaP, GaAs, or GaSb. In an implementation, the substrate 10 may be a silicon-on-insulator (SOI) substrate or a germanium-on-insulator (GOI) substrate. As used herein, the term “or” is not an exclusive term, e.g., “A or B” would include A, B, or A and B.

The first gate structure 161 may be in a first recess extending through an upper portion of a substrate 10, and may include, e.g., a gate insulation pattern 130, a first conductive pattern 135, a second conductive pattern 140, a third conductive pattern 145 and a gate mask 150.

The gate insulation pattern 130 may be on a bottom and a sidewall of the first recess, and the first to third conductive patterns 135, 140, and 145 and the gate mask may be sequentially stacked on a portion of the gate insulation pattern 130 on the bottom of the first recess.

The gate insulation pattern 130 may include, e.g., an oxide such as silicon oxide.

The first conductive pattern 135 may include a first metal or a first metal compound, and a second metal or silicon may be doped therein. In an implementation, the first conductive pattern 135 may include, e.g., i) the first metal doped with the second metal, ii) the first metal compound doped with the second metal, iii) the first metal doped with silicon, or iv) the first metal compound doped with silicon.

The second conductive pattern 140 may include a third metal. A work function of each of the first metal and the first metal compound included in the first conductive pattern 135 may be lower than or substantially the same as a work function of the third metal included in the second conductive pattern 140.

A work function of the second metal doped in the first conductive pattern 135 may be smaller than the work function of the first metal or the first metal compound included in the first conductive pattern 135. In an implementation, the work function of the second metal may be smaller than the work function of the third metal as well as the work function of the first metal or the first metal compound. Accordingly, a work function the first conductive pattern 135 including i) the first metal doped with the second metal or ii) the first metal compound doped with the second metal may be smaller than a work function of the second conductive pattern 140 including the third metal.

In an implementation, if the first metal and the first metal compound are doped with silicon, a work function thereof may be smaller than the work function of the first metal and the first compound not doped with silicon. Accordingly, a work function of the first conductive pattern 135 including iii) the first metal doped with silicon or iv) the first metal compound doped with silicon may be smaller than the work function of the second conductive pattern 140 including the third metal.

In an implementation, the first metal may include, e.g., tantalum (Ta) or molybdenum (Mo).

In an implementation, the first metal compound may include, e.g., a metal oxide such as La₂O₃, Sc₂O₃, Al₂O₃, MgO, HfO₂, Y₂O₃, or the like, a metal nitride such as LaN, TaN, TiN, TiSiN, TiAlN, AlN, or the like, or a metal carbide such as TiAlC or the like.

In an implementation, the second metal may include, e.g., a metal having a small work function such as lanthanum (La), scandium (Sc), hafnium (Hf), tantalum (Ta), or the like.

In an implementation, the first conductive pattern 135 may include TiN doped with La.

The first metal or the first compound of the first conductive pattern 135 may be doped with the second metal, which may have a small work function, or silicon, which may help reduce the work function of the first conductive pattern 135, and thus a flat band voltage (Vfb) of the first conductive pattern 135, which may depend on the work function thereof, may be lowered. Accordingly, the first conductive pattern 135 may have a small flat band voltage even without having a large volume, and the on-off operation of the first gate structure 161 including the first conductive pattern 135 may be performed even at a low voltage.

In an implementation, the third metal included in the second conductive pattern 140 may be a single crystal. In an implementation, the third metal may include, e.g., a metal with a low resistance such as molybdenum (Mo), ruthenium (Ru), copper (Cu), iridium (Ir), rhodium (Rh), or the like. In an implementation, the second conductive pattern 140 may include molybdenum (Mo).

In an implementation, the first conductive pattern 135 may not need to have a large volume to have a low flat band voltage, and thus the space for the second conductive pattern 140 may be secured within the first recess, and thus the first gate structure 161 including the second conductive pattern 140 may have a low resistance.

The third conductive pattern 145 may include a fourth metal or a second metal compound, and a fifth metal may be doped in the fourth metal or in the second metal compound.

In an implementation, the fourth metal may include, e.g., a low-resistance metal such as molybdenum (Mo), and the second metal compound may include, e.g., a metal nitride such as TiN, TiSiN, TiAlN, or the like, or a metal carbide such as TiAlC or the like.

In an implementation, the fifth metal may include a metal having a small work function, e.g., lanthanum (La), scandium (Sc), hafnium (Hf), tantalum (Ta), or the like. The fifth metal may be doped into the fourth metal or the second metal compound included in the third conductive pattern 145, a dipole may be created in the third conductive pattern 145, and thus a lower surface of the third conductive pattern 145 contacting the second conductive pattern 140 may be positively charged.

In an implementation, the third conductive pattern 145 may include TiN doped with lanthanum (La).

The gate mask 150 may include, e.g., an insulating nitride such as silicon nitride.

In an implementation, the first conductive pattern 135 included in the first gate structure 161 may be doped with the first metal or silicon, and thus the first conductive pattern 135 may not need to have a large volume to have a low flat band voltage. Accordingly, the space for the second conductive pattern that may be included in the first gate structure 161 and have a relatively low resistance may be sufficiently secured, and thus the first gate structure 161 may have a low resistance.

In an implementation, as described below with reference to FIG. 3, the second conductive pattern 140 may grow only in the vertical direction, and thus the second conductive pattern 140 may include a single crystal metal. Accordingly, the second conductive pattern 135 may have a low resistance.

In an implementation, the fourth metal or the second metal compound of the third conductive pattern 145 may be doped with the fifth metal, and thus the lower surface of the third conductive pattern 145 in contact (e.g., direct contact) with the second conductive pattern 140 may be positively charged. In an implementation, gate induced drain leakage (GIDL) may be effectively prevented or reduced. In an implementation, the third conductive pattern 145 may include a metal instead of polysilicon doped with impurities, and thus, the third conductive pattern 145 may have a low resistance.

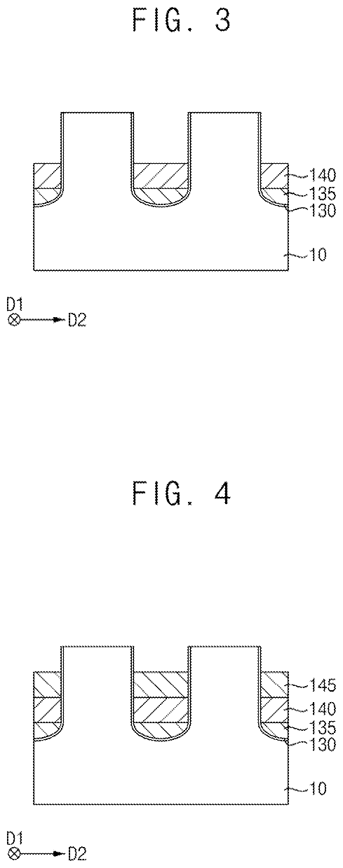

FIGS. 2 to 4 are cross-sectional views of stages in a method of forming a first gate structure in accordance with example embodiments.

Referring to FIG. 2, an upper portion of a substrate 10 may be removed to form a first recess, and a gate insulation pattern 130 may be conformally formed on an inner wall of the first recess.

A first conductive layer may be formed on the gate insulation pattern 130 and the substrate 10 to (e.g., at least partially) fill the first recess. The first conductive layer may include a first metal or a first metal compound.

In an implementation, the first conductive layer may be formed by a chemical vapor deposition (CVD) process, an atomic layer deposition (ALD) process, or a physical vapor deposition (PVD) process.

When the first conductive layer includes the first metal, the first conductive layer may be formed by a deposition process using a source gas of the first metal.

When the first conductive layer includes the first metal compound, the first conductive layer may be formed by performing a deposition process using a source gas of a metal included in the first metal compound together with an oxygen source gas, e.g., ozone plasma, a nitrogen source gas, e.g., ammonia, or a carbon source gas, e.g., methane.

An etch-back process may be performed on an upper portion of the first conductive layer to form a first preliminary conductive pattern. Accordingly, an upper surface of the first preliminary conductive pattern may be lower than an upper surface of the substrate 10.

A second metal may be doped and/or soaked in the first preliminary conductive pattern to form the first conductive pattern 135.

Referring to FIG. 3, the second conductive pattern 140 may be formed on the first conductive pattern 135, e.g., to fill a lower portion of the first recess.

In an implementation, the second conductive pattern 140 may be formed by a chemical vapor deposition (CVD) process using the first conductive pattern 135 as a seed, and the CVD process may proceed from the lower portion to an upper portion of the first recess. Accordingly, the third metal included in the second conductive pattern 140 may have a certain orientation. In an implementation, the second conductive pattern 140 may include a single crystal material.

In an implementation, the third metal may include molybdenum (Mo), and the CVD process may be performed by using a source gas, e.g., MoO₂Cl₂, MoCl₂, MoF₆, or the like. In an implementation, the second conductive pattern 140 may be formed by an atomic layer deposition (ALD) process or a physical vapor deposition (PVD) process.

Referring to FIG. 4, a third conductive layer may be formed on the second conductive pattern 140, the gate insulation pattern 130, and the substrate 10 to (e.g., at least partially) fill a portion of the first recess, e.g., a middle portion of the first recess.

The third conductive layer may include a fourth metal or a second metal compound, and may be formed by a chemical vapor deposition (CVD), an atomic layer deposition (ALD), or a physical vapor deposition (PVD) process.

When the third conductive layer includes the third metal, the third conductive layer may be formed by a deposition process using a source gas of the first metal.

When the third conductive layer includes the second metal compound, the third conductive layer may be formed by performing a deposition process using a source gas of a metal included in the second metal compound together with a nitrogen source gas, e.g., ammonia, or a carbon source gas, e.g., methane.

An etch-back process may be performed on an upper portion of the third conductive layer to form a third preliminary conductive pattern. Accordingly, an upper surface of the third preliminary conductive pattern may be lower than the upper surface of the substrate 10.

A fifth metal may be doped into the third preliminary conductive pattern to form third conductive pattern 145.

Referring to FIG. 1 again, a gate mask layer may be formed on the third conductive pattern 145, the gate insulation pattern 130, and the substrate 10 to fill a remaining portion of the first recess, and a planarization process may be performed on the gate mask layer until the upper surface of the substrate 10 is exposed to form the gate mask 150.

Accordingly, the first gate structure 161 including the gate insulation pattern 130, the first to third conductive patterns 135, 140, and 145, and the gate mask 150 may be formed.

The planarization process may include, e.g., a chemical mechanical polishing (CMP) process or an etch-back process.

In an implementation, the first conductive pattern 135 may be formed in the lower portion of the first recess, and the second conductive pattern 140 may be formed by the chemical vapor deposition (CVD) process using the first conductive pattern 135 as a seed. Thus, the second conductive pattern 140 may grow in the vertical direction.

If the first conductive pattern 135 were to be conformally formed on an inner wall of the gate insulation pattern 130 on the inner wall of the first recess, the first conductive pattern 135 could grow not only in the vertical direction but also in the horizontal direction by the CVD process, and portions of the second conductive pattern 140, which may grow in the horizontal direction from an inner sidewall of the gate insulation pattern 130 may meet each other at a lower central portion of the first recess. Van der Waals force could act between the portions of the second conductive pattern 140 that meet each other at the lower central portion of the first recess, and thus, the first gate structure 161 could bend.

In an implementation, the second conductive pattern 140 may grow only in the vertical direction by the CVD process. Accordingly, the second conductive pattern 140 may be formed to have a uniform orientation, and thus, the first gate structure 161 including the second conductive pattern 140 may not bend.

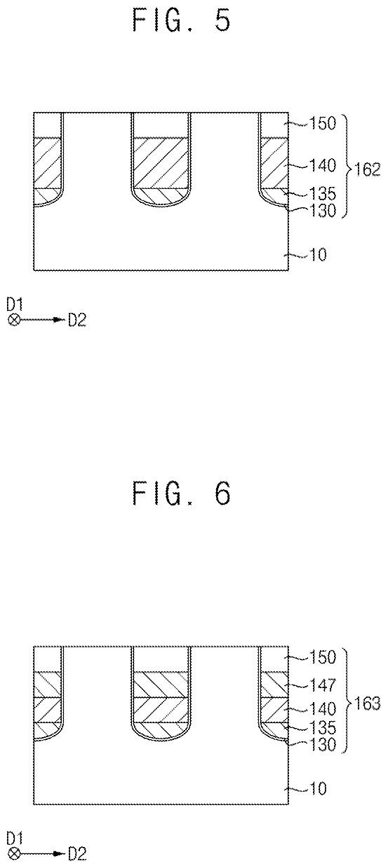

FIGS. 5 to 7 are cross-sectional views illustrating second to fourth gate structures 162, 163, and 164 in accordance with example embodiments. The second to fourth gate structures 162, 163 and 164 may be substantially the same as or similar to the first gate structure 161 illustrated with reference to FIG. 1, except for some elements, and thus repeated explanations may be omitted herein.

Referring to FIG. 5, the second gate structure 162 may include the gate insulation pattern 130, the first and second conductive pattern 135 and 140, and the gate mask 150 sequentially stacked, and may not include the third conductive pattern 145.

Accordingly, an upper surface of the second conductive pattern 140 may contact, instead of the lower surface of the third conductive pattern 145, a lower surface of the gate mask 150.

Referring to FIG. 6, the third gate structure 163 may include a fourth conductive pattern 147 instead of the third conductive pattern 145, and the third gate structure 163 may include the gate insulation pattern 130, the first, second, and fourth conductive patterns 135, 140, and 147, and the gate mask 150 sequentially stacked.

In an implementation, the fourth conductive pattern 147 may include polysilicon doped with impurities.

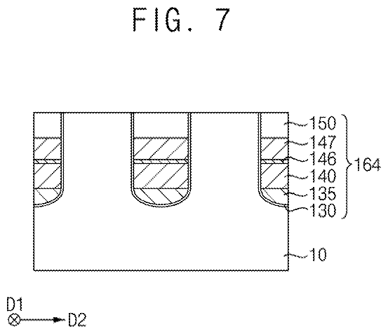

Referring to FIG. 7, the fourth gate structure 164 may further include a first barrier pattern 146 between the second and fourth conductive patterns 140 and 147, and thus the fourth gate structure 164 may include the gate insulation pattern 130, the first and second conductive patterns 135 and 140, the first barrier pattern 146, the fourth conductive patterns 147, and the gate mask 150 sequentially stacked.

The fourth conductive pattern 147 may include, e.g., polysilicon doped with impurities, and the first barrier pattern 146 may include, e.g., a metal nitride such as titanium nitride (TiN) or a metal silicon nitride such as titanium silicon nitride (TiSiN).

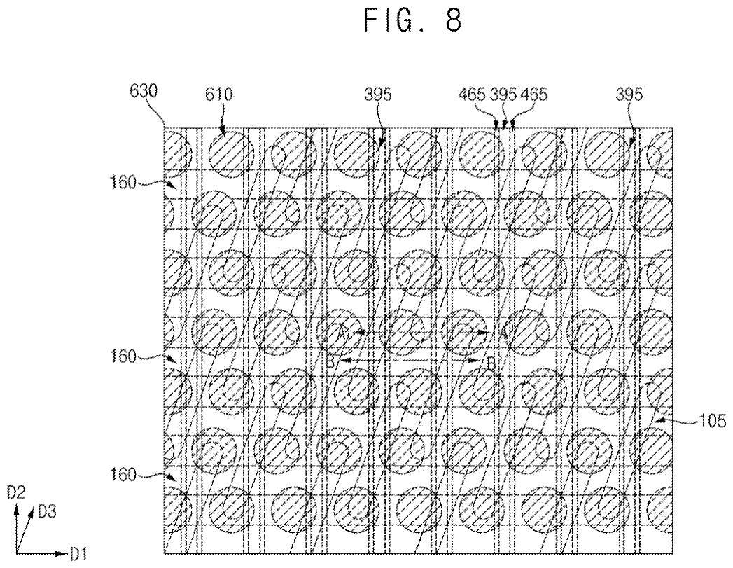

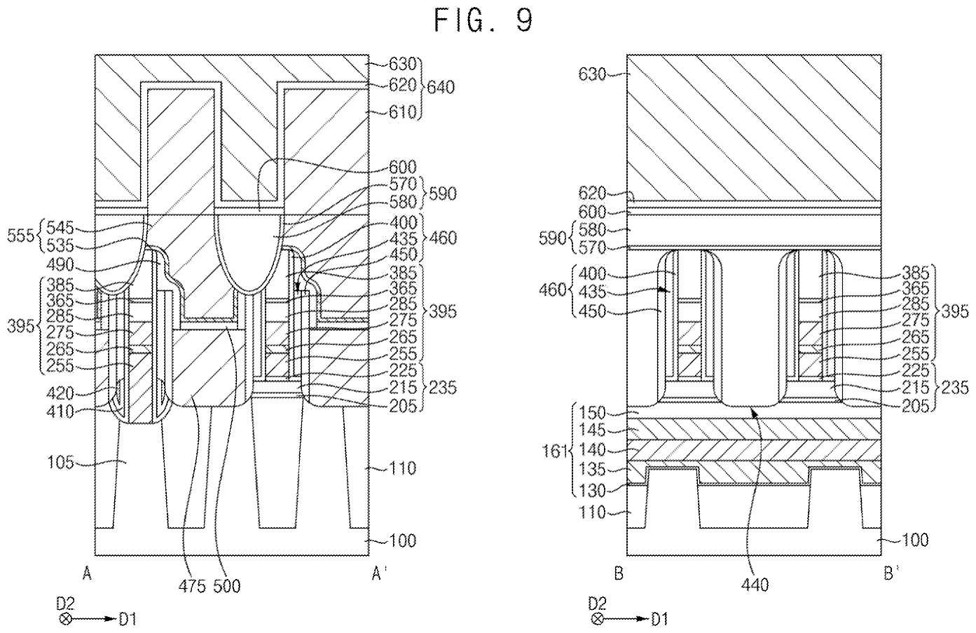

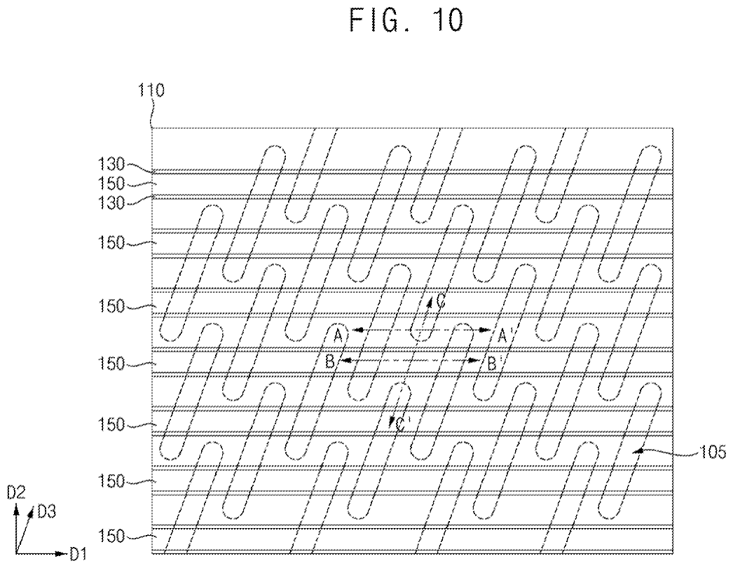

FIG. 8 is a plan view illustrating a semiconductor device in accordance with example embodiments, and FIG. 9 is a cross-sectional view taken along line A-A′ of FIG. 8.

This semiconductor device may be an application of the first gate structure illustrated with reference to FIG. 1 to a DRAM device, and thus repeated explanations on the first gate structure 161 may be omitted herein. In an implementation, the semiconductor device may include one of the second to fourth gate structures 162, 163 and 164 shown in FIGS. 5 to 7 instead of the first gate structure 161.

Referring to FIGS. 8 and 9, the semiconductor device may include an active pattern 105, the first gate structure 161, a bit line structure 395, a contact plug structure, and a capacitor structure 640 on the substrate 100.

The semiconductor device may further include an isolation pattern 110, a spacer structure 465, a fourth spacer 490, a second capping pattern 485, first and second insulation pattern structures 235 and 590, fourth and fifth insulation patterns 410 and 420, and a metal silicide pattern 500.

The active pattern 105 may extend in the third direction D3, and a plurality of active patterns 105 may be spaced apart from each other in the first and second directions D1 and D2. A sidewall of the active pattern 105 may be covered by the isolation pattern 110. The active pattern 105 may include substantially the same material as the substrate 100, and the isolation pattern 110 may include an oxide, e.g., silicon oxide.

Referring to FIGS. 8 and 9 together with FIG. 11, the first gate structure 161 may be formed in a third recess extending (e.g., lengthwise) in the first direction D1 through upper portions of the active pattern 105 and the isolation pattern 110. The first gate structure 161 may include the gate insulation pattern 130 on a bottom and a sidewall of the third recess, the first to third conductive pattern 135, 140, and 145 on a portion of the gate insulation pattern 130 on the bottom and a lower sidewall of the third recess, and the gate mask 150 on the third conductive pattern 145 and filling an upper portion of the third recess.

In an implementation, the first gate structure 161 may extend in the first direction D1, and a plurality of first gate structures 161 may be spaced apart from each other in the second direction D2.

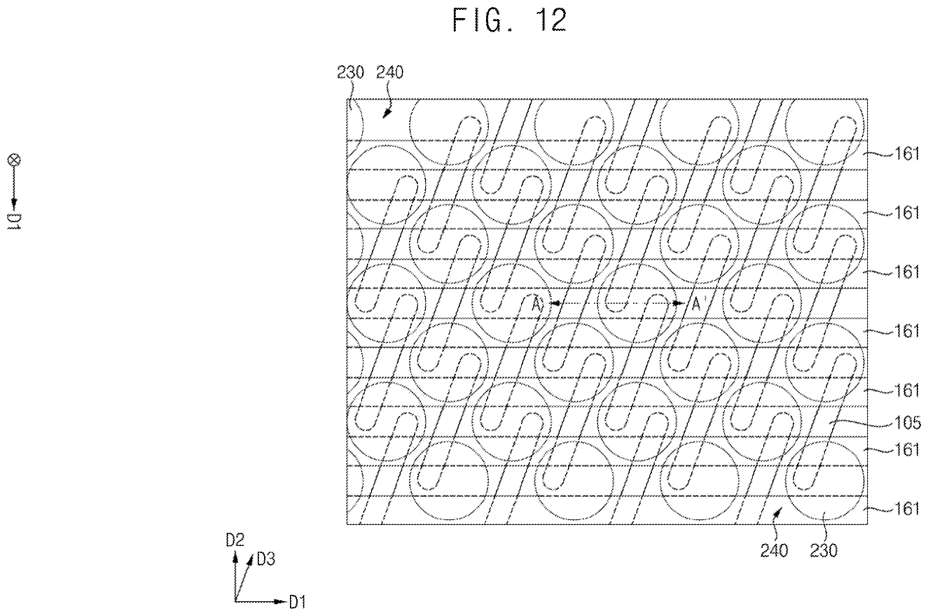

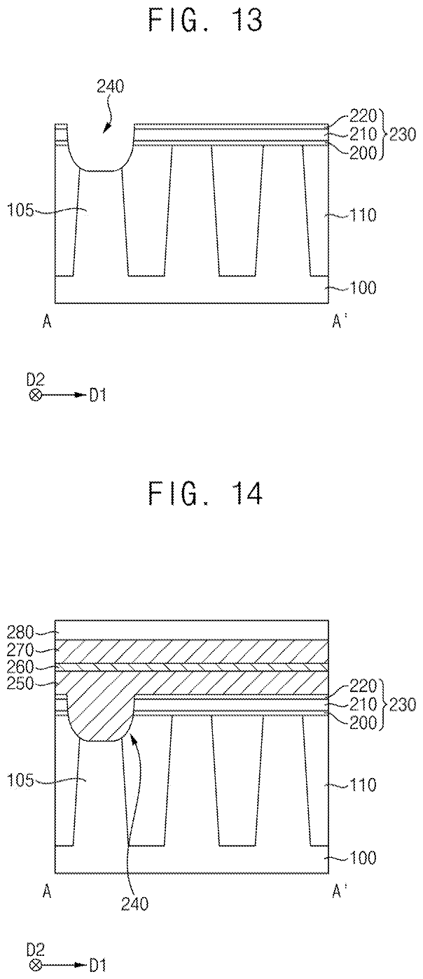

Referring to FIGS. 12 and 13 together with FIGS. 8 and 9, a first opening 240 extending through an insulating layer structure 230 and exposing upper surfaces of the active pattern 105, the isolation pattern 110 and the gate mask 150 of the first gate structure 161 may be formed, and an upper surface of a central portion in the third direction D3 of the active pattern 105 may be exposed by the first opening 240.

In an implementation, an area of a bottom of the first opening 240 may be greater than an area of the upper surface of the active pattern 105. Thus, the first opening 240 may also expose an upper surface of a portion of the isolation pattern 110 adjacent to the active pattern 105. In an implementation, the first opening 240 may extend through upper portions of the active pattern 105 and the portion of the isolation pattern 110 adjacent thereto, and the bottom of the first opening 240 may be lower than an upper surface of each of opposite edge portions in the third direction D3 of the active pattern 105.

The bit line structure 395 may include a fifth conductive pattern 255, a second barrier pattern 265, a sixth conductive pattern 275, a first mask 285, a first etch stop pattern 365 and a first capping pattern 385 sequentially stacked in the vertical direction on the first opening 240 or the first insulation pattern structure 235. The fifth conductive pattern 255, the second barrier pattern 265 and the sixth conductive pattern 275 may collectively form a conductive structure, and the first mask 285, the first etch stop pattern 365 and the first capping pattern 385 may collectively form an insulation structure.

The fifth conductive pattern 255 may include, e.g., doped polysilicon, the second barrier pattern 265 may include a metal nitride, e.g., titanium nitride, or a metal silicon nitride, e.g., titanium silicon nitride, the sixth conductive pattern 275 may include a metal, e.g., tungsten, and each of the first mask 285, the first etch stop pattern 365 and the first capping pattern 385 may include an insulating nitride, e.g., silicon nitride.

In an implementation, the bit line structure 395 may extend in the second direction D2 on the substrate 100, and a plurality of bit line structures 395 may be spaced apart from each other in the first direction D1.

The fifth and sixth insulation patterns 410 and 420 may be formed in the first opening 240, and may contact a lower sidewall of the bit line structure 395. The fifth insulation pattern 410 may include an oxide, e.g., silicon oxide, and the sixth insulation pattern 420 may include an insulating nitride, e.g., silicon nitride.

The first insulation pattern structure 235 may be formed on the active pattern 105 and the isolation pattern 110 under the bit line structure 395, and may include second to fourth insulation patterns 205, 215 and 225 sequentially stacked in the vertical direction. The second and fourth insulation patterns 205 and 225 may include an oxide, e.g., silicon oxide, and the third insulation pattern 215 may include an insulating nitride, e.g., silicon nitride.

The contact plug structure may include a lower contact plug 475, a metal silicide pattern 500 and an upper contact plug 555 sequentially stacked in the vertical direction on the active pattern 105 and the isolation pattern 110.

The lower contact plug 475 may contact the upper surface of each of opposite edge portions in the third direction D3 of the active pattern 105. In an implementation, a plurality of lower contact plugs 475 may be spaced apart from each other in the second direction D2, and a second capping pattern 485 may be formed between neighboring ones of the lower contact plugs 475 in the second direction D2. The second capping pattern 485 may include an insulating nitride, e.g., silicon nitride.

The lower contact plug 475 may include, e.g., doped polysilicon, and the metal silicide pattern 700 may include, e.g., titanium silicide, cobalt silicide, nickel silicide, or the like.

The upper contact plug 555 may include a second metal pattern 545 and a third barrier pattern 535 covering a lower surface of the second metal pattern 545. The second metal pattern 545 may include a metal, e.g., tungsten, and the third barrier pattern 535 may include a metal nitride, e.g., titanium nitride.

In an implementation, a plurality of upper contact plugs 555 may be spaced apart from each other in the first and second directions D1 and D2, and may be arranged in a honeycomb pattern or a lattice pattern in a plan view. Each of the upper contact plugs 555 may have a shape of, e.g., a circle, an ellipse, or a polygon in a plan view.

The spacer structure 465 may include a first spacer 400 covering sidewalls of the bit line structure 395 and the fourth insulation pattern 225, an air spacer 435 on a lower outer sidewall of the first spacer 400, and a third spacer 450 on an outer sidewall of the air spacer 435, a sidewall of the first insulation pattern structure 235, and upper surfaces of the fifth and sixth insulation patterns 410 and 420.

Each of the first and third spacers 400 and 450 may include an insulating nitride, e.g., silicon nitride, and the air spacer 435 may include air.

The fourth spacer 490 may be formed on an outer sidewall of a portion of the first spacer 400 on an upper sidewall of the bit line structure 395, and may cover an upper end of the air spacer 435 and an upper surface of the third spacer 450. The fourth spacer 490 may include an insulating nitride, e.g., silicon nitride.

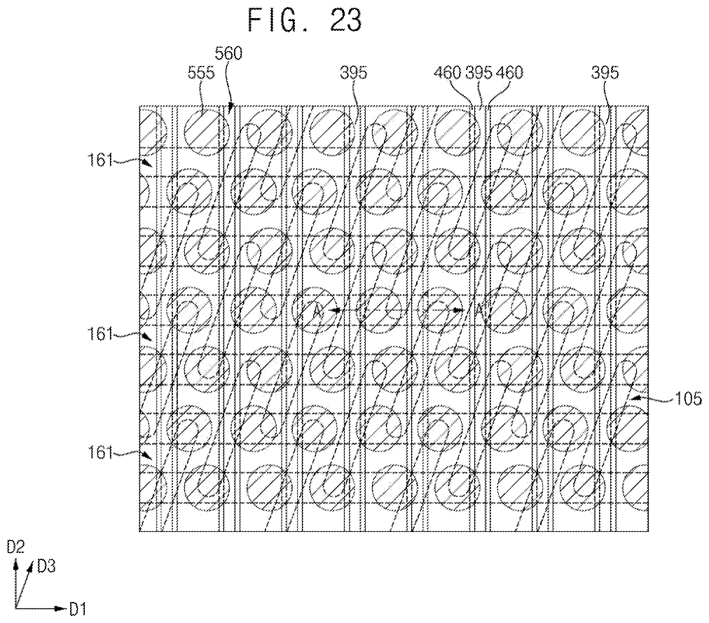

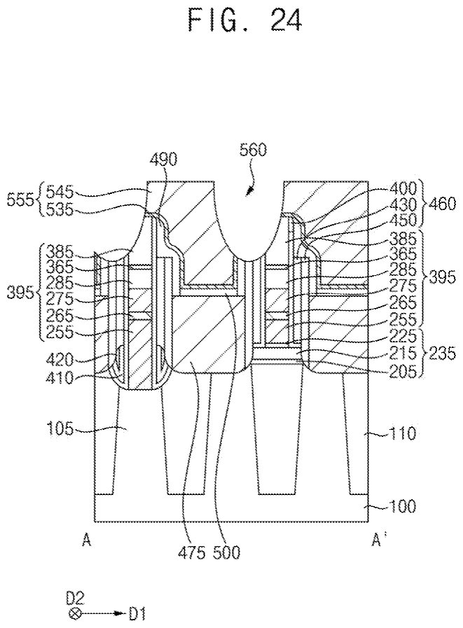

Referring to FIGS. 23 and 24 together with FIGS. 8 and 9, the second insulation pattern structure 590 may include a seventh insulation pattern 570 on an inner wall of an sixth opening 560, which may extend through the upper contact plug 555, a portion of the insulation structure of the bit line structure 395 and portions of the first, third and fourth spacers 400, 450 and 490 and surround the upper contact plug 555 in a plan view, and an eighth insulation pattern 580 on the seventh insulation pattern 570 and fill a remaining portion of the sixth opening 560. The upper end of the air spacer 435 may be closed by the seventh insulation pattern 570.

The seventh and eighth insulation patterns 570 and 580 may include an insulating nitride, e.g., silicon nitride.

The capacitor structure 640 may contact an upper surface of the upper contact plug 555. The capacitor structure 640 may include a lower electrode 610, a dielectric layer 620, and an upper electrode 630 sequentially stacked. Each of the lower electrode 610 and the upper electrode 630 may include, e.g., a metal, a metal nitride, a metal silicide, polysilicon doped with impurities, silicon-germanium doped with impurities, or the like, and the dielectric layer 620 may include, e.g., a metal oxide such as hafnium oxide or zirconium oxide.

The second etch stop pattern 600 may be formed on the seventh and eighth insulating patterns 770 and 780 and the second capping pattern 485.

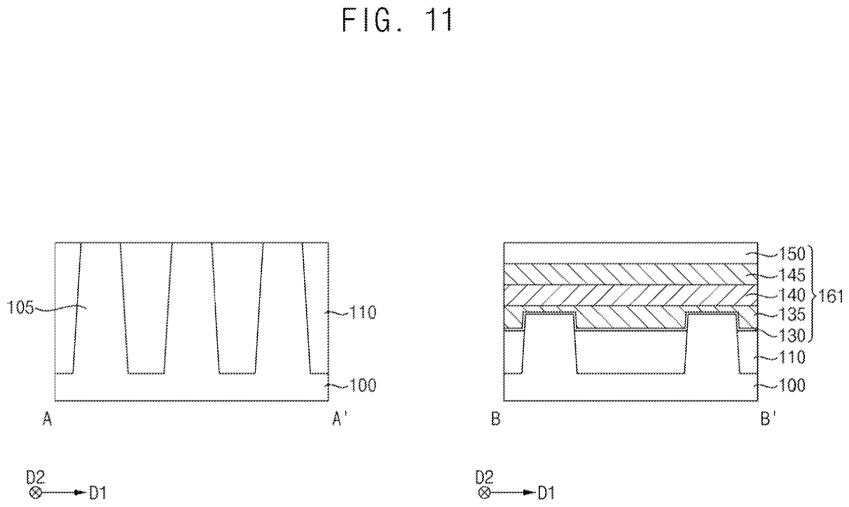

FIGS. 10 to 25 are plan views and cross-sectional views of stages in a method of manufacturing a semiconductor device according to example embodiments.

Specifically, FIGS. 10, 12, 15, 19 and 23 are the plan views, FIG. 11 includes cross-sectional views taken along lines A-A′ and B-B′ of FIG. 10, and FIGS. 13-14, 16-18, 20-22 and 24-25 are cross-sectional views taken along lines A-A′, respectively, of corresponding plan views.

The method of manufacturing the semiconductor device is an application of the method of forming the first gate structure described with reference to FIGS. 1 to 4 to a method of manufacturing a DRAM device, and repeated explanations of the method of forming the first gate structure may be omitted herein.

Referring to FIGS. 10 and 11, an upper portion of a substrate 100 may be removed to form a second recess, and an isolation pattern 110 may be formed in the second recess.

The isolation pattern 110 may be formed on the substrate 100, and an active pattern 105 of which a sidewall is covered by the isolation pattern 110 may be defined.

The active pattern 105 and the isolation pattern 110 on the substrate 100 may be partially etched to form a third recess extending in the first direction D1, and the first gate structure 161 may be formed in the third recess. In an implementation, the first gate structure 161 may extend in the first direction D1, and a plurality of first gate structures 161 may be spaced apart from each other in the second direction D2.

Referring to FIGS. 12 and 13, an insulating layer structure 230 may be formed on the active pattern 105, the isolation pattern 110, and the first gate structure 161. The insulating layer structure 230 may include second to fourth insulating layers 200, 210, and 220 sequentially stacked.

The insulating layer structure 230 may be patterned, and the active pattern 105, the isolation pattern 110, and the gate mask 150 included in the first gate structure 161 may be partially etched using the patterned insulating layer structure 230 as an etching mask to form a first opening 240. In an implementation, the insulating layer structure 230 may have a circular shape or an elliptical shape in a plain view, and a plurality of insulating layer structures 230 may be spaced apart from each other in the first and second directions D1 and D2. Each of the insulating layer structures 230 may overlap end portions of ones of the active patterns 105 neighboring in the third direction D3, which may face each other, in the vertical direction.

Referring to FIG. 14, a fourth conductive layer 250, a first barrier layer 260, a fifth conductive layer 270 and a first mask layer 280 may be sequentially stacked on the insulating layer structure 230, and the active pattern 105, the isolation pattern 110 and the first gate structure 161 exposed by the first opening 240. The fourth conductive layer 250, the first barrier layer 260, the fifth conductive layer 270 and the first mask layer 280 may collectively form a conductive structure layer. The first conductive layer 250 may fill the first opening 240.

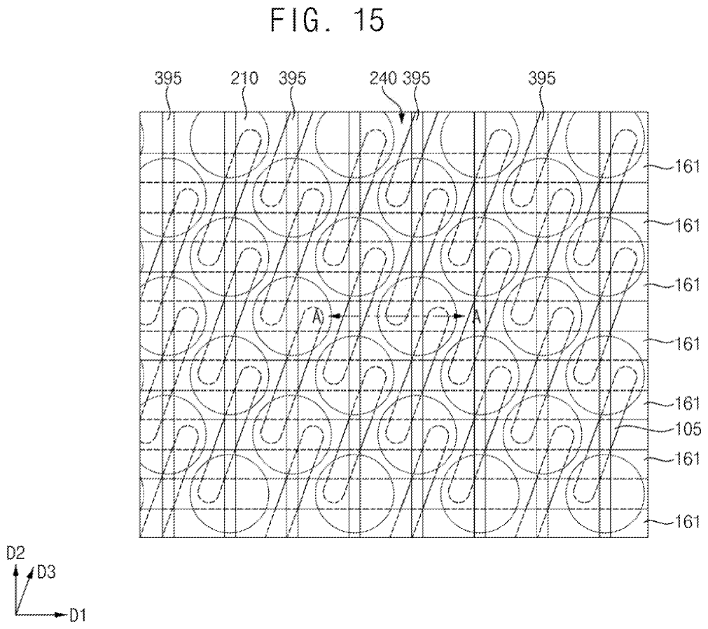

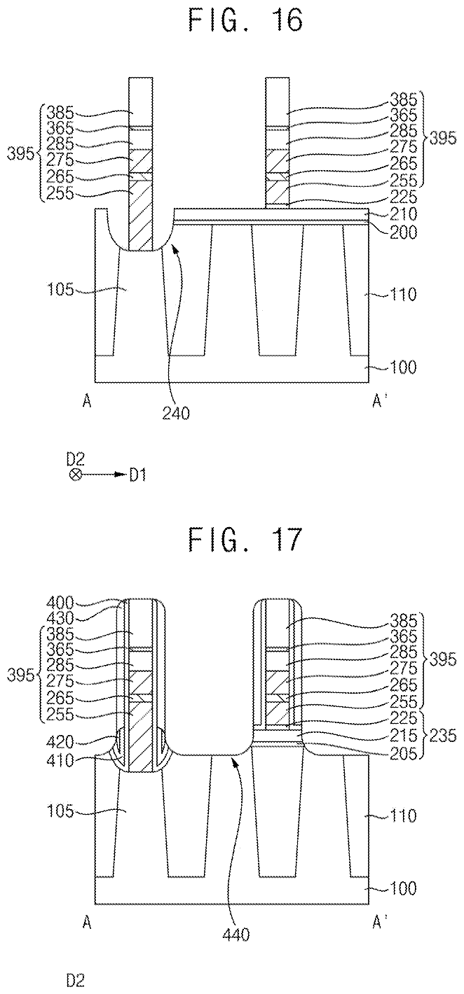

Referring to FIGS. 15 and 16, a first etch stop layer and a first capping layer may be sequentially formed on the conductive structure layer, the first capping layer may be etched to form a first capping pattern 385, and the first etch stop layer, the first mask layer 280, the fifth conductive layer 270, the first barrier layer 260 and the fourth conductive layer 250 may be sequentially etched using the first capping pattern 385 as an etching mask.

In an implementation, the first capping pattern 385 may extend in the second direction D2, and a plurality of first capping patterns 385 may be spaced apart from each other in the first direction D1.

By the etching process, a fifth conductive pattern 255, a second barrier pattern 265, a sixth conductive pattern 275, a first mask 285, a first etch stop pattern 365 and the first capping pattern 385 may be formed on the first opening 240, and a fourth insulation pattern 225, the fifth conductive pattern 255, the second barrier pattern 265, the sixth conductive pattern 275, the first mask 285, the first etch stop pattern 365 and the first capping pattern 385 may be sequentially stacked on the third insulating layer 210 of the insulating layer structure 230 at an outside of the first opening 240.

Hereinafter, the fifth conductive pattern 255, the second barrier pattern 265, the sixth conductive pattern 275, the first mask 285, the first etch stop pattern 365 and the first capping pattern 385 sequentially stacked may be referred to as a bit line structure 395. The fifth conductive pattern 255, the second barrier pattern 265 and the sixth conductive pattern 275 may collectively form a conductive structure, and the first mask 285, the etch stop pattern 365 and the first capping pattern 385 may collectively form an insulating structure. In an implementation, the bit line structure 395 may extend in the second direction D2, and a plurality of bit line structures 395 may be spaced apart from each other in the first direction D1.

Referring to FIG. 17, a first spacer layer may be formed on the substrate 100 on which the bit line structure 395 has been formed, and fifth and sixth insulating layers may be sequentially formed on the first spacer layer.

The first spacer layer may also cover a sidewall of the fourth insulation pattern 225 under the bit line structure 395 on the third insulating layer 210, and the sixth insulating layer may fill a remaining portion of the first opening 240.

The fifth and sixth insulating layers may be etched by an etching process. In an implementation, the etching process may be a wet etching process using, e.g., phosphoric acid (H₂PO₃), SC1, and hydrofluoric acid (HF) as an etchant, and portions of the fifth and sixth insulating layers except for portions thereof in the first opening 240 may be removed. In an implementation, most portion of a surface of the first spacer layer, e.g., all portions of the surface of the first spacer layer except for a portion of the surface thereof in the first opening 240 may be exposed, and the fifth and sixth insulating layers remaining in the first opening 240 may form fifth and sixth insulation patterns 410 and 420, respectively.

A second spacer layer may be formed on the exposed surface of the first spacer layer and the fifth and sixth insulation patterns 410 and 420 in the first opening 240. The second spacer layer may be anisotropically etched to form a second spacer 430 covering a sidewall of the bit line structure 395 on the surface of the first spacer layer and on the fifth and sixth insulation patterns 410 and 420.

A dry etching process may be performed using the first capping pattern 385 and the second spacer 430 as an etching mask to form a second opening 440 exposing an upper surface of the active pattern 105, and upper surfaces of the isolation pattern 110 the gate mask 150 may also be exposed by the second opening 440.

By the dry etching process, portions of the first spacer layer on upper surfaces of the first capping pattern 385 and the third insulating layer 210 may be removed, and thus a first spacer 400 may be formed on the sidewall of the bit line structure 395. By the dry etching process, the second and third insulating layers 200 and 210 may be partially removed to remain as second and third insulation patterns 205 and 215, respectively, under the bit line structure 395. The second to fourth insulation patterns 205, 215 and 225 sequentially stacked under the bit line structure 395 may collectively form a first insulation pattern structure 235.

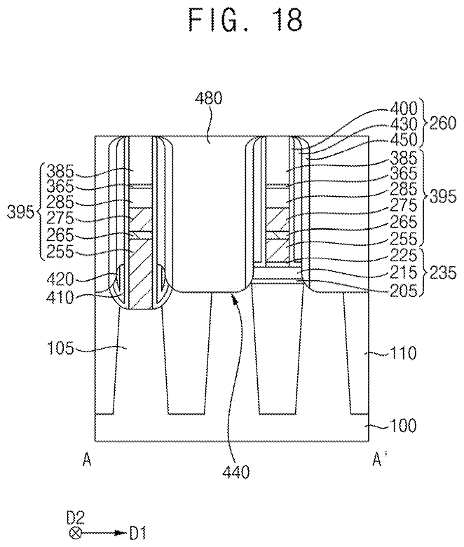

Referring to FIG. 18, a third spacer layer may be formed on the upper surface of the first capping pattern 385, an outer sidewall of the second spacer 430, portions of the upper surfaces of the fifth and sixth insulation patterns 410 and 420, and the upper surfaces of the active pattern 105, the isolation pattern 110 and the gate mask 150 exposed by the second opening 440. The third spacer layer may be anisotropically etched to form a third spacer 450 covering the sidewall of the bit line structure 395.

The first to third spacers 400, 430 and 450 sequentially stacked on the sidewall of the bit line structure 395 in the horizontal direction may be referred to as a preliminary spacer structure 460.

A sacrificial layer may be formed to fill the second opening 440 on the substrate 100 to a sufficient height, and an upper portion of the sacrificial layer may be planarized until the upper surface of the first capping pattern 385 is exposed to form a sacrificial pattern 480 in the second opening 440.

In an implementation, the sacrificial pattern 480 may extend in the second direction D2, and a plurality of sacrificial patterns 480 may be spaced apart from each other in the first direction D1 by the bit line structures 395. The sacrificial pattern 480 may include, e.g., an oxide such as silicon oxide.

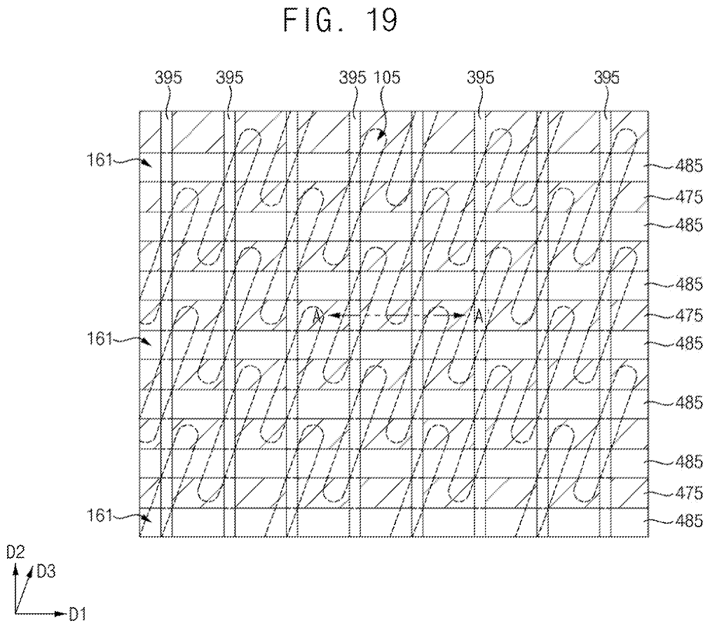

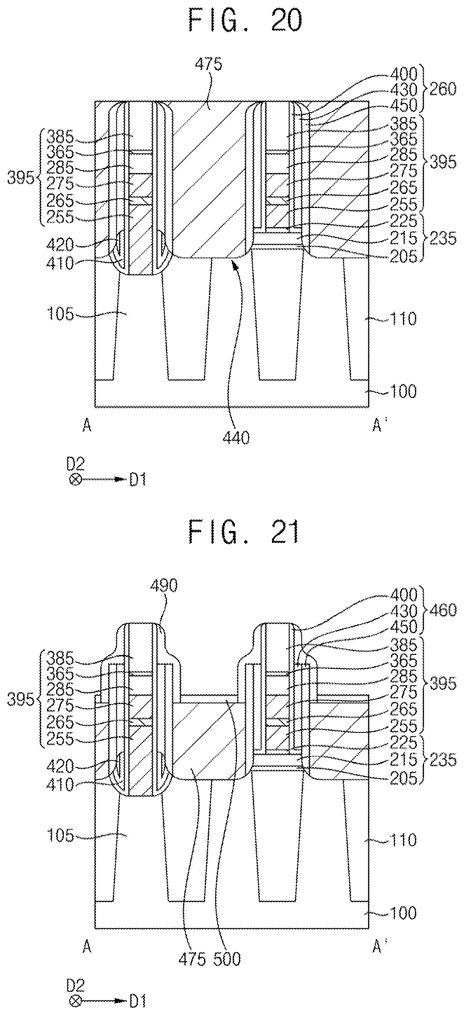

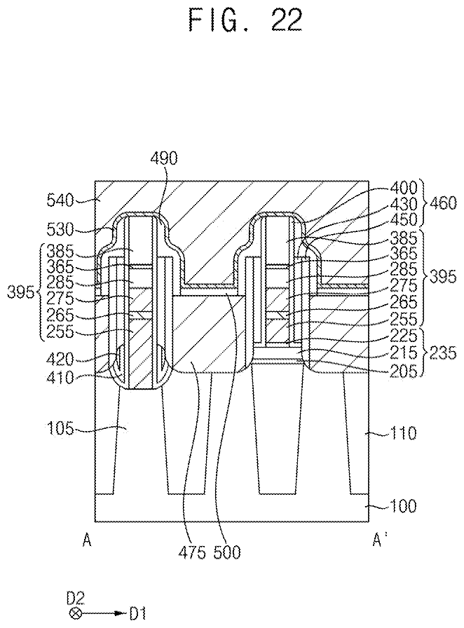

Referring to FIGS. 19 and 20, a second mask including a plurality of third openings, each of which may extend in the first direction D1, spaced apart from each other in the second direction D2 may be formed on the first capping pattern 385, the sacrificial pattern 480 and the preliminary spacer structure 460, and may be etched using the fourth mask as an etching mask.

In an implementation, each of the third openings may overlap a region between the first gate structures 161 in the vertical direction. By the etching process, a fourth opening exposing upper surfaces of the active pattern 105 and the isolation pattern 110 may be formed between the bit line structures 395 on the substrate 100.

The second mask may be removed, a lower contact plug layer may be formed to fill the fourth opening to a sufficient height, and an upper portion of the lower contact plug layer may be planarized until the upper surface of the first capping pattern 385 and upper surfaces of the sacrificial pattern 480 and the preliminary spacer structure 460 are exposed. Thus, a plurality of lower contact plugs 475 spaced apart from each other in the second direction D2 may be formed between the bit line structures 395. Additionally, the sacrificial pattern 480 extending in the second direction D2 between the bit line structures 395 may be divided into a plurality of parts in the second direction D2 by the lower contact plugs 475.

The sacrificial pattern 480 may be removed to form a fifth opening, and a second capping pattern 485 may be formed to fill the seventh opening. In an implementation, the second capping pattern 485 may overlap the first gate structure 161 in the vertical direction.

Referring to FIG. 21, an upper portion of the lower contact plug 475 may be removed to expose an upper portion of the preliminary spacer structure 460 on the sidewall of the bit line structure 395, and upper portions of the second and third spacers 430 and 450 of the exposed preliminary spacer structure 460 may be removed.

An upper portion of the lower contact plug 475 may be additionally removed. Thus, an upper surface of the lower contact plug 475 may be lower than upper surfaces of the second and third spacers 430 and 450.

A fourth spacer layer may be formed on the bit line structure 395, the preliminary spacer structure 460, the second capping pattern 485 and the lower contact plug 475, and may be anisotropically etched to form a fourth spacer 490 covering an upper portion of the preliminary spacer structure 460 on the sidewall of the bit line structure 395, and the upper surface of the lower contact plug 475 may be exposed by the etching process.

A metal silicide pattern 500 may be formed on the exposed upper surface of the lower contact plug 475. In an implementation, the metal silicide pattern 500 may be formed by forming a first metal layer on the first and second capping patterns 385 and 485, the fourth spacer 490 and the lower contact plug 475, performing a heat treatment thereon, and removing an unreacted portion of the first metal layer.

Referring to FIG. 22, a second barrier layer 530 may be formed on the first and second capping patterns 385 and 485, the fourth spacer 490, the metal silicide pattern 500 and the lower contact plug 475, and a second metal layer 540 may be formed on the second barrier layer 530 to fill a space between the bit line structures 395.

A planarization process may be performed on an upper portion of the second metal layer 540. The planarization process may include, e.g., a chemical mechanical polishing (CMP) process or an etch-back process.

Referring to FIGS. 23 and 24, the second metal layer 540 and the second barrier layer 530 may be patterned to form an upper contact plug 555. In an implementation, a plurality of upper contact plugs 555 may be formed, and a sixth opening 560 may be formed between the upper contact plugs 555.

The sixth opening 560 may be formed by partially removing the first and second capping patterns 385 and 485, the preliminary spacer structure 460 and the fourth spacer 490 as well as the second metal layer 540 and the second barrier layer 530.

The upper contact plug 555 may include a second metal pattern 545 and a third barrier pattern 535 covering a lower surface of the second metal pattern 755. In an implementation, the upper contact plug 555 may have a shape of a circle, an ellipse, or a rounded polygon in a plan view, and the upper contact plugs 555 may be arranged, e.g., in a honeycomb pattern in the first and second directions D1 and D2, in a plan view.

The lower contact plug 475, the metal silicide pattern 500 and the upper contact plug 555 sequentially stacked on the substrate 100 may collectively form a contact plug structure.

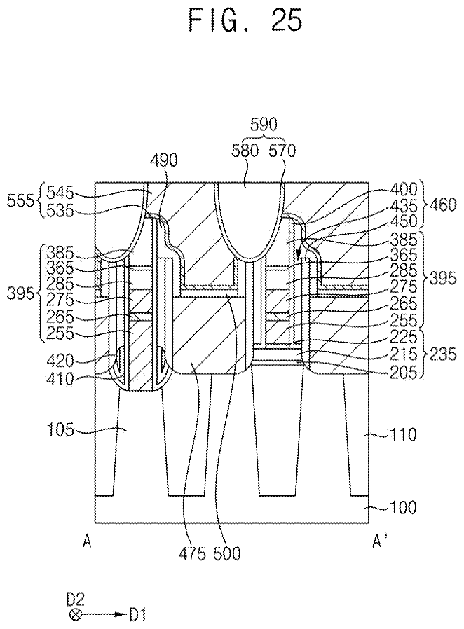

Referring to FIG. 25, the second spacer 430 included in the preliminary spacer structure 460 exposed by the sixth opening 560 may be removed to form an air gap, a seventh insulation pattern 570 may be formed on a bottom and a sidewall of the sixth opening 560, and an eighth insulation pattern 580 may be formed to fill a remaining portion of the sixth opening 560.

Each of the seventh and eighth insulation patterns 570 and 580 may form a second insulation pattern structure 590.

An upper end of the air gap may be covered by the seventh insulation pattern 570, and thus an air spacer 435 may be formed. The first spacer 400, the air spacer 435 and the third spacer 450 may collectively form a spacer structure 465.

Referring to FIGS. 8 and 9 again, a capacitor structure 640 may be formed to contact an upper surface of the upper contact plug 555.

In an implementation, a second etch stop pattern 600 and a mold layer may be sequentially stacked on the first upper contact plug 555 and the second insulation pattern structure 590, and the second etch stop pattern 600 and the mold layer may be partially etched to form a seventh opening partially exposing the upper surface of the upper contact plug 555.

A plurality of seventh openings exposing the upper surfaces of the upper contact plugs 555, respectively, may be arranged in a honeycomb pattern or a lattice pattern in a plan view.

A lower electrode 610 having, e.g., a shape of a pillar, may be formed to fill the seventh opening, the mold layer may be removed, and a first dielectric layer 620 and an upper electrode 630 may be formed on the lower electrode 610 and the second etch stop pattern 600. The lower electrode 610, the dielectric layer 620, and the upper electrode 630 may collectively form the capacitor structure 640.

In an implementation, the lower electrode 610 may have a shape of cylinder.

Upper wirings may be further formed to complete the fabrication of the semiconductor device.

By way of summation and review, as the degree of integration of the DRAM device increases, a volume of the gate structure may decrease, and thus electrical characteristics of the gate structure may deteriorate.

One or more embodiments may provide a gate structure having improved characteristics.

One or more embodiments may provide a semiconductor device including a gate structure having improved characteristics.

In the semiconductor device according to example embodiments, the gate structure may include the first to third conductive patterns. The second conductive pattern having a relatively low resistance may have a large volume and include a single-crystal metal, and thus the gate structure may have low resistance as a whole. In addition, the first conductive pattern may be doped with a metal having a small work function or silicon, and thus the gate structure may have a low flat band voltage. Furthermore, the third conductive pattern may be doped with a metal creating a dipole so that an interface with the second conductive pattern may be positively charged, and thus induced drain leakage (GIDL) may be effectively prevented or reduced.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A gate structure, comprising:
a first conductive pattern including a first metal or a first metal compound and being doped with a second metal or silicon;
a second conductive pattern on the first conductive pattern, the second conductive pattern including a third metal; and
a gate insulation pattern covering a lower surface and a sidewall of the first conductive pattern and a sidewall of the second conductive pattern;
wherein a work function of the second metal is smaller than a work function of the first metal and is smaller than a work function of the first metal compound.

2. The gate structure as claimed in claim 1, wherein the first metal includes tantalum (Ta).

3. The gate structure as claimed in claim 1, wherein the first metal compound includes La₂O₃, Sc₂O₃, Al₂O₃, MgO, HfO₂, Y₂O₃, LaN, TaN, TiN, TiSiN, TiAlN, AlN, or TiAlC.

4. The gate structure as claimed in claim 1, wherein:
the first conductive pattern is doped with the second metal, and
the second metal includes lanthanum (La), scandium (Sc), or hafnium (Hf).

5. The gate structure as claimed in claim 1, wherein the third metal includes molybdenum (Mo), ruthenium (Ru), copper (Cu), iridium (Ir), or rhodium (Rh).

6. The gate structure as claimed in claim 1, further comprising a third conductive pattern on the second conductive pattern,
wherein the third conductive pattern includes polysilicon doped with impurities.

7. The gate structure as claimed in claim 6, further comprising a barrier pattern between the second conductive pattern and the third conductive pattern.

8. The gate structure as claimed in claim 6, further comprising a gate mask on the third conductive pattern,
wherein the gate insulation pattern covers a sidewall of the gate mask.

9. A gate structure, comprising:
a first conductive pattern including a first metal compound and being doped with a first metal or silicon;
a second conductive pattern on the first conductive pattern, the second conductive pattern including a second metal; and
a third conductive pattern on the second conductive pattern, the third conductive pattern being doped with a fourth metal and including a third metal or a second metal compound,
wherein a work function of the first metal is smaller than a work function of the first metal compound.

10. The gate structure as claimed in claim 9, wherein:
the first conductive pattern is doped with the first metal, and
the first metal includes lanthanum (La), scandium (Sc), hafnium (Hf), or tantalum (Ta).

11. The gate structure as claimed in claim 9, wherein the first metal compound includes La₂O₃, Sc₂O₃, Al₂O₃, MgO, HfO₂, Y₂O₃, LaN, TaN, TiN, TiSiN, TiAlN, AlN, or TiAlC.

12. The gate structure as claimed in claim 9, wherein the second metal includes molybdenum (Mo), ruthenium (Ru), copper (Cu), iridium (Ir), or rhodium (Rh).

13. The gate structure as claimed in claim 9, wherein:
the third conductive pattern includes the third metal, and
the third metal includes molybdenum (Mo).

14. The gate structure as claimed in claim 9, wherein:
the third conductive pattern includes the second metal compound, and
the second metal compound includes TiN, TiSiN, TiAlN, or TiAlC.

15. The gate structure as claimed in claim 9, the fourth metal includes lanthanum (La), scandium (Sc), hafnium (Hf), or tantalum (Ta).

16. A semiconductor device, comprising:
a substrate;
an active pattern on the substrate;
an isolation pattern covering a sidewall of the active pattern;
a gate structure extending through upper portions of the active pattern and the isolation pattern in a first direction substantially parallel to an upper surface of the substrate;
a bit line structure on a central portion of the active pattern, the bit line structure extending in a second direction substantially parallel to the upper surface of the substrate;
a contact plug structure contacting each opposite end portions of the active pattern; and
a capacitor structure on the contact plug structure;
wherein:
the gate structure includes:
a first conductive pattern including a first metal compound, the first conductive pattern being doped with a first metal or silicon,
a second conductive pattern on the first conductive pattern, the second conductive pattern including a second metal,
a third conductive pattern on the second conductive pattern,
a gate mask on the third conductive pattern, and
a gate insulation pattern covering a lower surface and a sidewall of the first conductive pattern, a sidewall of the second conductive pattern, and a sidewall of the third conductive pattern, and
a work function of the first metal is smaller than a work function of the first metal compound.

17. The semiconductor device as claimed in claim 16, wherein:
the first metal includes lanthanum (La), scandium (Sc), hafnium (Hf), or tantalum (Ta), and
the first metal compound includes La₂O₃, Sc₂O₃, Al₂O₃, MgO, HfO₂, Y₂O₃, LaN, TaN, TiN, TiSiN, TiAlN, AlN, or TiAlC.

18. The semiconductor device as claimed in claim 16, wherein the second metal includes molybdenum (Mo), ruthenium (Ru), copper (Cu), iridium (Ir), or rhodium (Rh).

19. The semiconductor device as claimed in claim 16, wherein the third conductive pattern includes polysilicon doped with impurities.

20. The semiconductor device as claimed in claim 16, wherein the third conductive pattern is doped with a fourth metal and includes a third metal or a second metal compound.
